(19) United States
(12) Patent Application Publication
(10) Pub. No.: US 2009/0000092 A1
(43) Pub. Date: Jan. 1, 2009

(54) Method for the manufacture of a piezoelectric actuator

(76) Inventor: Bertram Sugg, Gerlingen (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/230,475

(22) Filed: Aug. 29, 2008

Related U.S. Application Data
(62) Division of application No. 10/540,026, filed on Jan. 25, 2006.

(30) Foreign Application Priority Data
Dec. 23, 2002 (DE) 1 02 60 853.9

(51) Int. Cl. H01L 41/24

(52) U.S. Cl. 29/25.35; 29/25.42; 310/334; 333/189

(57) ABSTRACT

A piezoelectric actuator comprised of a multi-layered construction of piezoelectric layers interleaved with inner electrodes in which the inner electrodes are contacted on alternating sides by outer electrodes and the regions between the outer electrodes are provided with a suitable insulation has an insulating layer which is comprised of a material with properties virtually identical to those of the piezoelectric layers which is applied to the external surface of the piezoelectric actuator in the region between the outer electrodes.

### CROSS-REFERENCE TO RELATED APPLICATIONS

This application is a divisional application of Ser. No. 10/540,026, filed Jan. 25, 2006, which in turn is a 35 USC 371 application of PCT/DE03/02132 filed on Jun. 26, 2003.

### BACKGROUND OF THE INVENTION

1. Field of the Invention

The invention relates to an improved piezoelectric actuator, for example for actuating a mechanical component such as a valve or the like.

2. Description of the Prior Art

It is generally known that the so-called piezoelectric effect can be used to produce a piezoelectric element partly comprised of ceramic material with a suitable crystalline structure. When an external electrical voltage is applied, a mechanical reaction of the piezoelectric element occurs, which produces a pressure or tension in a direction that can be predetermined as a function of the crystalline structure and the regions to which the electrical voltage is applied. Such piezoelectric actuators are particularly suitable for use in quick, precise switching processes, for example in various systems of gasoline or diesel injection in injectors for internal combustion engines.

The construction of these piezoelectric actuators can be laid out in a number of layers, in the form of so-called multi-layered piezoelectric actuators in which the layers are respectively interleaved with the inner electrodes used to apply the electrical voltage. To this end, piezoelectric sheets are produced and stacked in alternation with printed electrode surfaces that serve as inner electrodes. A sheet has its connection on only one connection side; on the opposite side, an edge must remain that has an insulating space, but no inner electrode. Then the two sides are externally connected by means of outer electrodes. The piezoelectric actuator is thus constructed in an intrinsically known way with a number of plates, much like a capacitor.

These multi-layered piezoelectric actuators are manufactured out of slip in an intrinsically known way, using a so-called sheet casting process. The resulting so-called green sheets are laminated after being stacked and are then sintered. The desired geometry is obtained either through hard machining in the sintered state or through shaping while in the green state, i.e. before the sintering. As a rule, this process is only used to manufacture a piezoelectric actuator that will be protected from moisture and mechanical damage.

As mentioned above, in most inner electrode designs, one surface of the piezoelectric actuator has inner electrodes of alternating polarities respectively protruding from its surface. There is the danger here of short circuits occurring between the electrode layers due to insufficient insulation or due to mechanical damage during transport, reconfiguration, or operation. This can in fact be counteracted by means of so-called semi-embedded or fully embedded inner electrode designs. In this case, either no electrodes or exclusively inner electrodes of one particular polarity are routed outward to surfaces not needed for contacting purposes. However, this method requires precise and therefore expensive stacking and/or cutting procedures.

For example, DE 199 28 180 A1 has disclosed that in the region between the contacts of the outer electrodes, the piezoelectric layers can be recessed inward a predetermined amount in order to form a groove. During machining of the surface of the piezoelectric actuator and during attachment of the outer electrodes, this groove prevents the electrode material from spreading between the outer electrodes and therefore results in a significant improvement in the electric strength of the piezoelectric actuator.

### SUMMARY AND ADVANTAGES OF THE INVENTION

The piezoelectric actuator described at the beginning, which can be used, for example, to actuate a mechanical component, is comprised of a multi-layered construction of piezoelectric layers interleaved with inner electrodes. The inner electrodes are contacted on alternating sides by outer electrodes, the regions between the outer electrodes being provided with a suitable insulation. According to the present invention, an insulating layer comprised of a preferably ceramic material with properties virtually identical to those of the piezoelectric layers, e.g. slip, is advantageously applied to the outer surface of the piezoelectric actuator in the region between the outer electrodes. It is particularly advantageous to use the same exact slip that was used during the sheet casting of the piezoelectric layers.

The outer electrodes can easily be attached to regions in which the insulating material has been ground away.

According to one advantageous manufacturing method, in a first process step, during the green state of the piezoelectric actuator, i.e. before the sintering, the insulating layer is applied to the entire outside of the piezoelectric actuator. To that end, the piezoelectric actuator can be completely immersed in the slip. The piezoelectric actuator can optionally also be coated only on the sensitive sides from which the inner electrodes of the two polarities protrude outward. A suitable process for this is the so-called dip immersion process.

The present invention can produce coating thicknesses typically in the range of 50-400 μm. This layer thickness decreases by 10-30% after sintering, depending on the sintering shrinkage. The viscosity of the slip and/or the application of multiple coatings can be used to achieve a particular layer thickness. A suitable layer thickness here assures a sufficient layer spacing of the inner electrodes from the surface, thus preventing arc-overs between the inner electrodes. Furthermore, the layer thickness should be chosen so as to prevent cracking during operation.

If the insulating protective layer is manufactured using the same ceramic material that was used when manufacturing the piezoelectric actuator itself, then the subsequent sintering produces a very tight, integral bond between the ceramic of the sheet laminations of the piezoelectric layers and the outer insulating layer; this ceramic layer constitutes an effective protective sleeve around the actuator. With closed porosity, which is usually the case with the piezoelectric ceramic used, the ceramic layer is quite impermeable to moisture with sufficient layer thickness. After the piezoelectric actuator is sintered, the regions in which the outer electrodes are contacted and possibly also the end surfaces are uncovered, for example by means of grinding or etching.

This advantageously produces a short-circuit-proof piezoelectric actuator and it is safe to use the piezoelectric actuator even in the presence of increased moisture. This also permits, an improved handling of the piezoelectric actuator and obviates the need for insulating lacquer.

### BRIEF DESCRIPTION OF THE DRAWINGS

An exemplary embodiment of the piezoelectric actuator will be more fully explained herein below, in conjunction with the drawings, in which:

FIG. 1 shows a section through a piezoelectric actuator with a multi-layered construction of piezoelectric ceramic layers and electrodes according to the prior art,

FIG. 2 shows a view of a piezoelectric actuator according to the present invention, with a protective layer and an uncovered outer electrode,

FIG. 3 shows a section A-A through the piezoelectric actuator according to FIG. 2,

FIGS. 4 and 5 each show a cross section through a piezoelectric actuator after sintering, one before and one after the uncovering of the outer electrode regions of the piezoelectric actuator, and

FIGS. 6 and 7 show top views of the inner electrode design of the piezoelectric actuator.

### DESCRIPTION OF THE PREFERRED EMBODIMENT

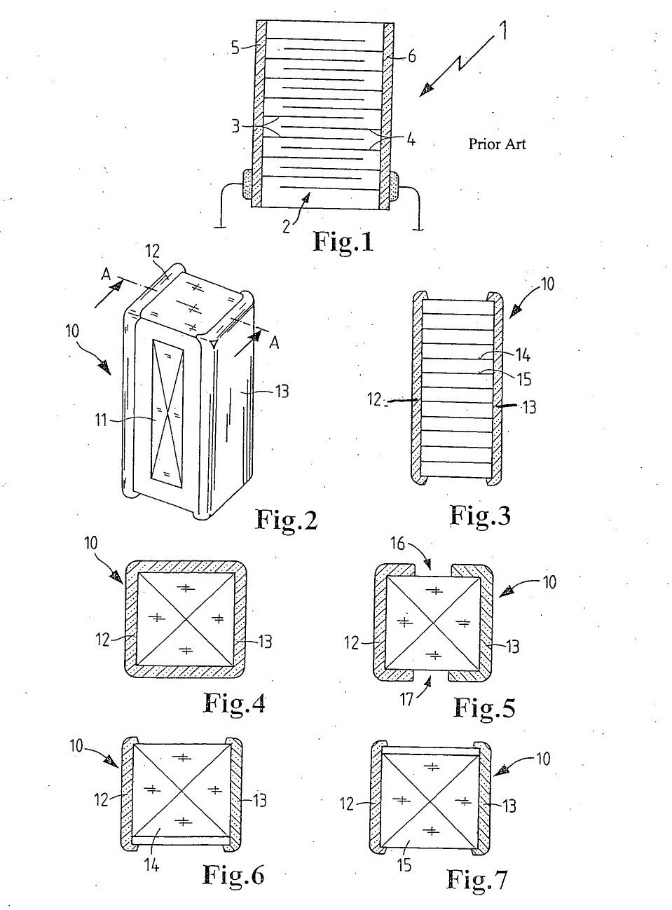

FIG. 1 schematically depicts a piezoelectric actuator 1 according to the prior art, which is comprised in an intrinsically known manner of piezoelectric layers or piezoelectric sheets 2 of a quartz material with a suitable crystalline structure so that by means of the so-called piezoelectric effect, an external application of electrical voltage to the inner electrodes 3 and 4 via contact surfaces or outer electrodes 5 and 6 triggers a mechanical reaction of the piezoelectric actuator 1.

FIG. 2 shows a piezoelectric actuator 10 according to the present invention, which has insulating layers 12 and 13 comprised of a preferably ceramic material with properties virtually identical to those of the piezoelectric layers 2, preferably slip, on its outside surfaces in the region between the outer electrodes—only one outer electrode 11 is visible here.

FIG. 3 shows a section A-A according to FIG. 2 in which the inner electrodes 14, 15 and the layers 12 and 13 are also shown.

In order to explain the manufacturing process, FIG. 4 depicts the so-called green state of the piezoelectric actuator 10, i.e. before the sintering. The insulating layer 12, 13 here is initially applied to all surfaces of the piezoelectric actuator 10. To that end, the piezoelectric actuator 10 can be completely immersed in the slip serving as a material for the insulating layers 12 and 13 or the stationary piezoelectric actuator 10 can be wetted in a bath of slip; the fill level of the slip can be raised and lowered.

FIG. 5 shows the state after the sintering of the piezoelectric actuator 10. Here, regions 16 and 17 to be contacted by the outer electrodes 111 are uncovered by grinding or etching, thus producing the insulating layers 12 and 13.

FIGS. 6 and 7 show top views of the inner electrode design of the inner electrode 14 (FIG. 6) and the inner electrode 15 (FIG. 7). It is clear from these figures that the outer electrodes respectively contact the inner electrodes 14 in the region 16 shown in FIG. 5 and the inner electrodes 15 in the region 17.

The foregoing relates to preferred exemplary embodiments of the invention, it being understood that other variants and embodiments thereof are possible within the spirit and scope of the invention, the latter being defined by the appended claims.

I claim:

1-8. (canceled)

9. A method for manufacturing a piezoelectric actuator which comprises
a multi-layered construction of piezoelectric layers (2) interleaved with inner electrodes (3, 4; 14, 15), and
an alternating contacting of the inner electrodes (3, 4; 14, 15) with outer electrodes (5, 6; 11), the regions between the outer electrodes (5, 6; 11) being provided with an insulation (12, 13) comprised of a material with properties virtually identical to those of the piezoelectric layers (2), the insulating layer (12, 13) being applied to the outer surface of the piezoelectric actuator (1; 10) in the region between the outer electrodes (5, 6; 11), the method comprising the steps of:
applying the insulating layer (12, 13) to all of the external surfaces of the piezoelectric actuator (10) in the green state of the piezoelectric actuator,
sintering the piezoelectric actuator (10), and
uncovering the regions (16, 17) in which the outer electrodes (5, 6; 11) are contacted, after sintering the piezoelectric actuator.

10. A method for manufacturing a piezoelectric actuator which comprises
a multi-layered construction of piezoelectric layers (2) interleaved with inner electrodes (3, 4; 14, 15), and
an alternating contacting of the inner electrodes (3, 4; 14, 15) with outer electrodes (5, 6; 11), the regions between the outer electrodes (5, 6; 11) being provided with an insulation (12, 13) comprised of a material with properties virtually identical to those of the piezoelectric layers (2), the insulating layer (12, 13) being applied to the outer surface of the piezoelectric actuator (1; 10) in the region between the outer electrodes (5, 6; 11), wherein the insulating layer (12, 13) encloses the edges of the piezoelectric actuator (1; 10), the method comprising the steps of:
applying the insulating layer (12, 13) to all of the external surfaces of the piezoelectric actuator (10) in the green state of the piezoelectric actuator,
sintering the piezoelectric actuator (10), and
uncovering the regions (16, 17) in which the outer electrodes (5, 6; 11) are contacted, after sintering the piezoelectric actuator.

11. A method for manufacturing a piezoelectric actuator which comprises
a multi-layered construction of piezoelectric layers (2) interleaved with inner electrodes (3, 4; 14, 15), and
an alternating contacting of the inner electrodes (3, 4; 14, 15) with outer electrodes (5, 6; 11), the regions between the outer electrodes (5, 6; 11) being provided with an insulation (12, 13) comprised of a material with properties virtually identical to those of the piezoelectric layers (2), the insulating layer (12, 13) being applied to the outer surface of the piezoelectric actuator (1; 10) in the region between the outer electrodes (5, 6; 11), wherein the insulating material is slip, the method comprising the steps of:
applying the insulating layer (12, 13) to all of the external surfaces of the piezoelectric actuator (10) in the green state of the piezoelectric actuator,
sintering the piezoelectric actuator (10), and
uncovering the regions (16, 17) in which the outer electrodes (5, 6; 11) are contacted, after sintering the piezoelectric actuator.

12. The method according to claim 9, wherein the step of applying the insulating layer comprises dipping the piezoelectric actuator (10) into the still fluid insulating layer, or wetting the piezoelectric actuator (10) with the fluid insulating material either on all sides or on two sides.

13. The method according to claim 10, wherein the step of applying the insulating layer comprises dipping the piezoelectric actuator (10) into the still fluid insulating layer, or wetting the piezoelectric actuator (10) with the fluid insulating material either on all sides or on two sides.

14. The method according to claim 11, wherein the step of applying the insulating layer comprises dipping the piezoelectric actuator (10) into the still fluid insulating layer, or wetting the piezoelectric actuator (10) with the fluid insulating material either on all sides or on two sides.

15. The method according to claim 9, wherein the regions (16, 17) that are contacted by the outer electrodes (5, 6; 11) are uncovered by means of grinding.

16. The method according to claim 10, wherein the regions (16, 17) that are contacted by the outer electrodes (5, 6; 11) are uncovered by means of grinding.

17. The method according to claim 11, wherein the regions (16, 17) that are contacted by the outer electrodes (5, 6; 11) are uncovered by means of grinding.

18. The method according to claim 9, wherein the regions (16, 17) that are contacted by the outer electrodes (5, 6; 11) are uncovered by means of etching.

19. The method according to claim 10, wherein the regions (16, 17) that are contacted by the outer electrodes (5, 6; 11) are uncovered by means of etching.

20. The method according to claim 11, wherein the regions (16, 17) that are contacted by the outer electrodes (5, 6; 11) are uncovered by means of etching.
